(19) United States
(12) Patent Application Publication
(10) Pub. No.: US 2017/0069649 A1
(43) Pub. Date: Mar. 9, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Shigeto OOTA, Yokkaichi (JP); Hiroyasu TANAKA, Yokkaichi (JP); Kohei NAKAGAMI, Yokkaichi (JP); Shingo NAKAJIMA, Yokkaichi (JP)

(73) Assignee: Kabushiki Kaisha Toshiba, Minato-ku (JP)

(21) Appl. No.: 15/007,571

(22) Filed: Jan. 27, 2016

Related U.S. Application Data
(60) Provisional application No. 62/214,751, filed on Sep. 4, 2015.

(51) Int. Cl. H01L 27/115; H01L 21/768; H01L 23/535

(52) U.S. Cl. CPC H01L 27/11573; H01L 27/1157; H01L 27/11582; H01L 23/535; H01L 21/76805; H01L 21/76829; H01L 21/76895

(57) ABSTRACT

According to one embodiment, a semiconductor memory device includes a substrate, a first semiconductor region, a second semiconductor region, an insulating layer, a gate electrode film, a gate insulating film, a first film, a second film, a first contact plug, and a second contact plug. The second film and the first film are arranged in the first direction. The first contact plug extends in the first film along a second direction. The second direction crosses the first direction. The first contact plug electrically connects to the first semiconductor region. The second contact plug extends in the second film along the second direction. The second contact plug electrically connects to the second semiconductor region. At least a part of the gate electrode film dose not overlap the first film in the second direction and dose not overlap the second film in the second direction.

### CROSS-REFERENCE TO RELATED APPLICATIONS

This application is based upon and claims the benefit of priority from U.S. Provisional Patent Application 62/214,751, filed on Sep. 4, 2015; the entire contents of which are incorporated herein by reference.

### FIELD

Embodiments described herein relate generally to a semiconductor memory device and a method for manufacturing the same.

### BACKGROUND

In recent years, semiconductor memory devices that achieve a higher integration of memory cells by integrating the memory cells three-dimensionally have been proposed. In such three-dimension stacked semiconductor memory devices, improvement in transistor characteristics is demanded.

### BRIEF DESCRIPTION OF THE DRAWINGS

FIG. 1 is a cross-sectional view illustrating a semiconductor memory device according to an embodiment;

FIGS. 2 to 8 are process sectional views illustrating the example of the manufacturing method for the semiconductor memory device according to the embodiment;

FIG. 9 is a cross-sectional view illustrating another example of a semiconductor memory device;

FIG. 10A is a cross-sectional view illustrating a region corresponding to the region R1 illustrated in FIG. 1, and FIG. 10B is a graph showing the relation between gate voltage and capacitance; and

FIG. 11A is a cross-sectional view illustrating a region corresponding to the region R2 illustrated in FIG. 1, and FIG. 11B is a graph illustrating the relation between the drain current and the gate voltage.

### DETAILED DESCRIPTION

According to one embodiment, a semiconductor memory device includes a substrate, a first semiconductor region, a second semiconductor region, an insulating layer, a gate electrode film, a gate insulating film, a first stopper film, a second stopper film, a first contact plug, and a second contact plug. The first semiconductor region and the second semiconductor region provide at a gap from each other in a first direction on the substrate. The insulating layer provides on the substrate, on the first semiconductor region, and on the second semiconductor region. The gate electrode film provides between an intermediate region of the substrate between the first semiconductor region and the second semiconductor region, and the insulating layer. The gate insulating film provides between the intermediate region and the gate electrode film. The first stopper film provides in the insulating layer. The second stopper film provides in the insulating layer and aligns in the first direction with respect to the first stopper film. The first contact plug extends inside the insulating layer and the first stopper film along a second direction, the second direction crosses the first direction, and the first contact plug electrically connects to the first semiconductor region. The second contact plug extends inside the insulating layer and the second stopper film along the second direction, the second contact plug electrically connects to the second semiconductor region. At least a portion of the first stopper film overlaps at least a portion of the second stopper film in the first direction. The gate electrode film includes a portion overlapping neither the first stopper film nor the second stopper film in the second direction.

Embodiment of the invention will be described hereinafter with reference to the accompanying drawings.

Note that, the drawings are schematic or conceptual. Relations between thicknesses and widths of portions, ratios of sizes among the portions, and the like are not always the same as real ones. Even when the same portions are shown, the portions are sometimes shown in different dimensions and ratios depending on the drawings. Note that in the specification and the drawings, components described with reference to the drawings already referred to are denoted by the same reference numerals and signs. Detailed description of the components is omitted as appropriate.

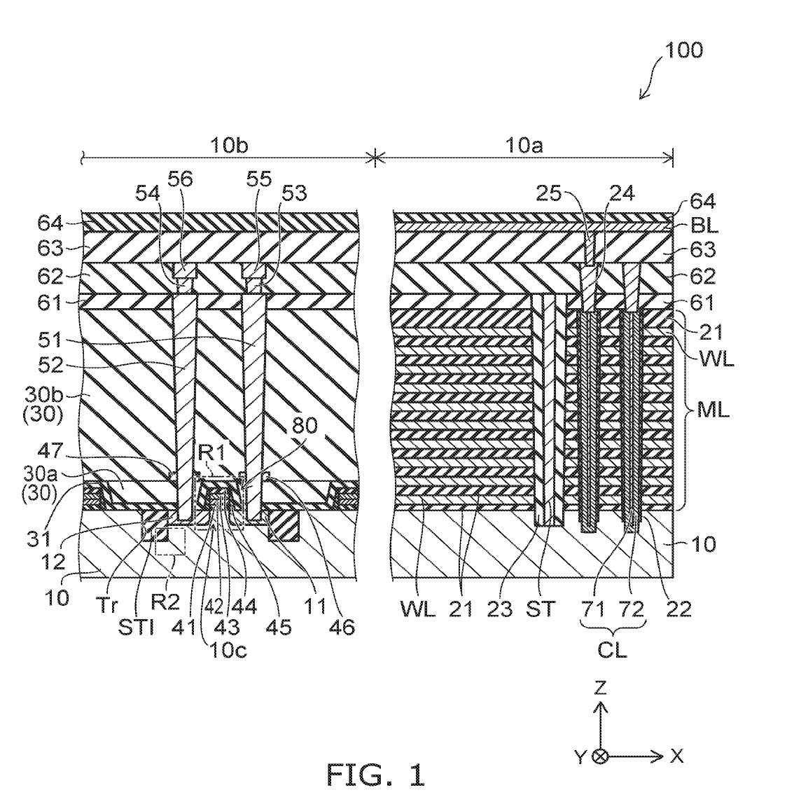

FIG. 1 is a cross-sectional view illustrating a semiconductor memory device according to an embodiment.

As illustrated in FIG. 1, a semiconductor memory device 100 according to an embodiment includes a memory cell region 10a and a peripheral circuit region 10b. The semiconductor memory device 100 is provided with a substrate 10. The substrate 10 is provided across both the memory cell region 10a and the peripheral circuit region 10b.

The direction perpendicular to a primary surface of the substrate 10 is the Z-direction (second direction). A direction perpendicular to the Z-direction is defined as the X-direction (first direction). A direction perpendicular to the Z-direction and the X-direction is defined as the Y-direction (third direction).

In the memory cell region 10a, a stacked body ML, columns CL, and a conductive film ST are provided on the substrate 10. The stacked body ML includes a plurality of electrode layers WL arranged in the Z-direction. Insulators are provided respectively between the electrode layers WL. The insulators are inter-electrode insulating layers 21, for example, but may alternatively be air gaps.

The columns CL extend inside the stacked body ML in the stacking direction (Z-direction). The columns CL are formed so as to be cylindrical or elliptic cylindrical, for example.

The column CL includes a core insulating member 71 and a semiconductor film 72. The core insulating member 71 extends in the Z-direction. The semiconductor film 72 is provided between the stacked body ML and the core insulating member 71, and between the substrate 10 and the core insulating member 71.

A memory film 22 is provided between the column CL and the stacked body ML. The memory film 22 includes a block insulating film, a charge storage film, and a tunnel insulating film. The block insulating film is provided between the stacked body ML and the column CL. The tunnel insulating film is provided between the block insulating film and each column CL. The charge storage film is provided between the tunnel insulating film and the block insulating film.

The block insulating film is a film through which a current does not substantially flow even when a voltage within the range of the driving voltage of the semiconductor memory device 100 is applied. The charge storage film is a film with the capability of storing electrical charges. The tunnel insulating film is typically an insulating film, but when a prescribed voltage within the range of the driving voltage of the semiconductor memory device 100 is applied, a tunnel current flows through the tunnel insulating film.

The tunnel insulating film and the block insulating film contain a silicon oxide, for example. The tunnel insulating film and the block insulating film may contain Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, or AlSiO. The charge storage film contains a silicon nitride, for example.

An insulating film 61 is provided on the stacked body ML, the memory film 22, and the columns CL. The conductive film ST extends in the insulating film 61 and the stacked body ML in the Z-direction and the Y-direction.

The insulating film 23 is provided between the conductive film ST and the stacked body ML, and between the conductive film ST and the insulating film 61. The insulating film 23 extends in the stacked body ML in the Z-direction and the X-direction.

In an insulating film 62 and the insulating film 61, first connecting members 24 are provided on the columns CL. An insulating film 63 is provided on the insulating film 62 and the first connecting member 24. In the insulating film 63, a second connecting member 25 is provided on a first connecting member 24. An insulating film 64 is provided above the insulating film 63 and the second connecting member 25. A bit line BL is provided in the insulating film 64. The bit line BL extends in the X-direction, for example. The bit line BL is connected to the column CL through the first connecting member 24 and the second connecting member 25.

In the peripheral circuit region 10b, trenches Tr are provided in the substrate 10. The trenches Tr have a groove shape extending in the Y-direction. Device isolation films STI are provided in the trenches Tr. The device isolation films STI contain an insulating material such as a silicon oxide, for example. A first semiconductor region 11 and a second semiconductor region 12 are provided at a gap from each other in portions of the substrate 10.

A gate insulating film 41 is provided between the first semiconductor region 11 and the second semiconductor region 12, and on the substrate 10. A semiconductor film 42 is provided on the gate insulating film 41. A gate electrode film 43 is provided on the semiconductor film 42. An insulating film 44 is provided on the gate electrode film 43.

An insulating layer 30 is provided above the substrate 10, the device isolation films STI, the first semiconductor region 11, the insulating film 44, and the second semiconductor region 12. An insulating film 31 is provided between the substrate 10 and the insulating layer 30, between the device isolation film STI and the insulating layer 30, between the first semiconductor region 11 and the insulating layer 30, between the insulating film 44 and the insulating layer 30, and between the second semiconductor region 12 and the insulating layer 30.

A side wall insulating film 45 is provided between the side wall of the semiconductor film 42 and the insulating film 31, between the side wall of the gate electrode film 43 and the insulating film 31, and between the side wall of the insulating film 31 and the insulating film 31.

A first stopper film 46 and a second stopper film 47 are provided at a gap from each other in the insulating layer 30. At least a portion of the first stopper film 46 and at least a portion of the first semiconductor region 11 overlap in the Z-direction, for example. At least a portion of the second stopper film 47 and at least a portion of the second semiconductor region 12 overlap in the Z-direction, for example. The first stopper film 46 and the second stopper film 47 have a shape similar to that of an island and are disposed at a gap from each other, for example. The insulating layer 30 includes a first insulating layer 30a and a second insulating layer 30b, for example. The first insulating layer 30a is provided between the second insulating layer 30b and the substrate 10. The first stopper film 46 and the second stopper film 47 are provided between the first insulating layer 30a and the second insulating layer 30b. The second insulating layer 30b is disposed integrally and continuously with the top surface of the first stopper film 46, the side surface of the first stopper film 46, the top surface of the second stopper film 47, and the side surface of the second stopper film 47, for example.

The insulating film 61 is provided on the insulating layer 30. A first contact plug 51 is provided over the first semiconductor region 11 so as to extend in the Z-direction through the insulating film 61, the insulating layer 30, the first stopper film 46, and the insulating film 31. The first contact plug 51 is electrically connected to the first semiconductor region 11. The first contact plug 51 is substantially cylindrical, for example.

A second contact plug 52 is provided over the second semiconductor region 12 so as to extend in the Z-direction through the insulating film 61, the insulating layer 30, the second stopper film 47, and the insulating film 31. The second contact plug 52 is electrically connected to the second semiconductor region 12. The second contact plug 52 is substantially cylindrical, for example. The side surface of the first contact plug 51 is in contact with the first insulating layer 30a, the second insulating layer 30b, and the first stopper film 46, for example. The side surface of the second contact plug 52 is in contact with the first insulating layer 30a, the second insulating layer 30b, and the second stopper film 47, for example.

The insulating layer 30 contains a silicon oxide, for example. The first stopper film 46 contains a silicon nitride, for example. The second stopper film 47 contains a silicon nitride, for example.

As described above, the insulating layer 30 is provided above the substrate 10, the first semiconductor region 11, and the second semiconductor region 12. The gate insulating film 43 is provided between the area of the first semiconductor region 11 and the second semiconductor region 12, and the insulating layer 30. The gate insulating film 41 is provided between the substrate 10 and the gate electrode film 43. The semiconductor film 42 is provided between the gate insulating film 41 and the gate electrode film 43. At least a portion of the gate electrode film 43 overlaps neither the first stopper film 46 nor the second stopper film 47 in the Z-direction. The first stopper film 46 and the second stopper film 47 may be connected to each other in a portion thereof.

The first semiconductor region 11, the second semiconductor region 12, the substrate 10, the gate insulating film 41, the semiconductor film 42, and the gate electrode film 43 function as a transistor 80, for example. Either the first semiconductor region 11 or the second semiconductor region 12 may be a drain region with the other being a source region. The substrate 10 includes an intermediate region 10c between the first semiconductor region 11 and the second semiconductor region 12. The intermediate region 10c is a channel region 10c, for example. The intermediate region 10c is a first conductivity type, and the first semiconductor region 11 and the second semiconductor region 12 are a second conductivity type, for example. The first conductivity type is the p-type conductivity, for example, whereas the second conductivity type is the n-type conductivity, for example. The first conductivity type may alternatively be the n-type conductivity, for example. In such a case, the second conductivity type is the p-type conductivity, for example.

The insulating film 62 is provided on the insulating film 61, the first contact plug 51, and the second contact plug 52. In the insulating film 62, a first plug 53 is provided on the first contact plug 51. In the insulating film 62, a second plug 54 is provided on the second contact plug 52.

In the insulating film 62, a first interconnection 55 extending in the Y-direction, for example, is provided on the first plug 53. The first interconnection 55 is electrically connected to the first contact plug 51 through the first plug 53. In the insulating film 62, a second interconnection 56 extending in the Y-direction, for example, is provided on the second plug 54. The second interconnection 56 is electrically connected to the second contact plug 52 through the second plug 54.

The insulating film 63 is provided on the insulating film 62, the first interconnection 55, and the second interconnection 56. The insulating film 64 is provided on the insulating film 63.

The following is a method for manufacturing the semiconductor memory device according to the embodiment.

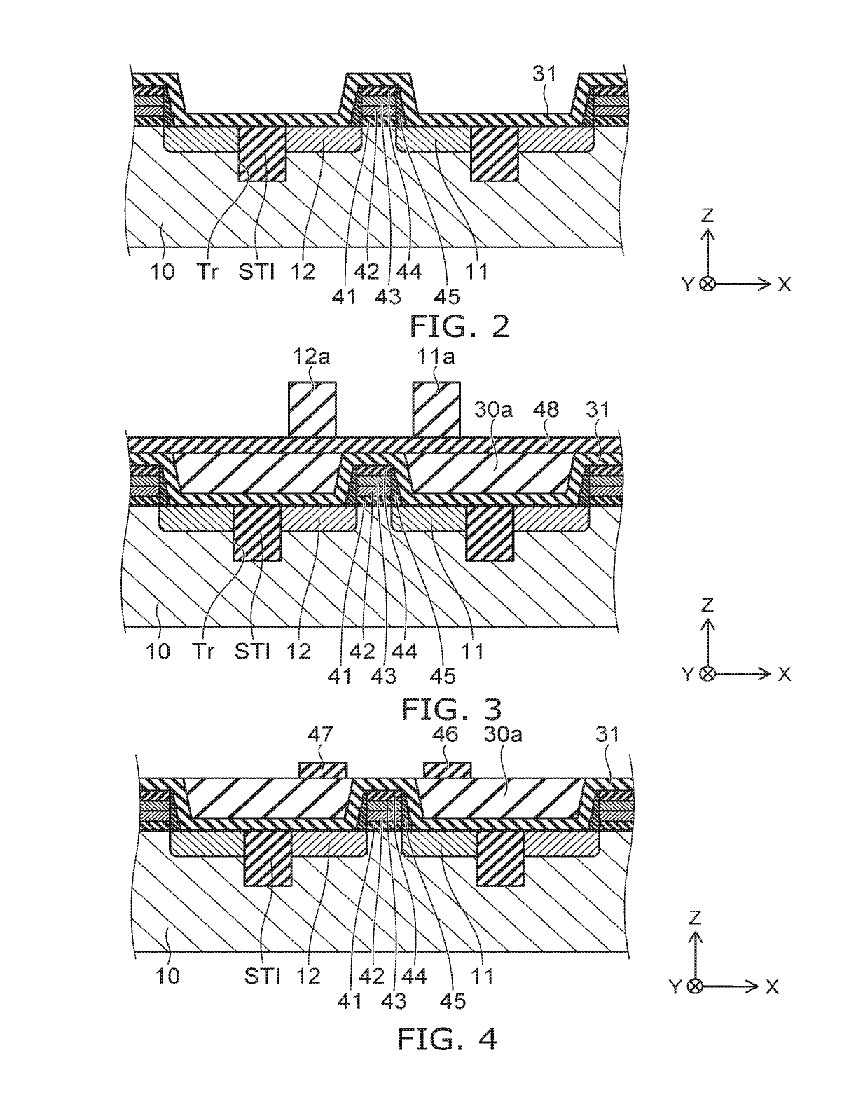

FIGS. 2 to 8 are process sectional views illustrating the example of the manufacturing method for the semiconductor memory device according to the embodiment.

As illustrated in FIG. 2, the trenches Tr are formed on the substrate 10. By providing an insulating material in the trenches Tr, the device isolation films STI are formed. The device isolation films STI are formed using a material containing a silicon oxide, for example.

The gate insulating film 41 is formed on the substrate 10. The semiconductor film 42 is formed on the gate insulating film 41. The gate electrode film 43 is formed on the semiconductor film 42. The insulating film 44 is formed on a prescribed portion of the gate electrode film 43. Anisotropic etching such as reactive-ion etching (RIE) is performed with the insulating film 44 as a mask. In this manner, the semiconductor film 42 and the gate electrode film 43 are processed into a prescribed pattern. A portion of the gate insulating film 41 is exposed in a portion where the semiconductor film 42 and the gate electrode film 43 have been removed.

The exposed portion of the gate insulating film 41 is removed by wet etching. At this time, the portion of the gate insulating film 41 disposed between the substrate 10 and the semiconductor film 42 remains. After depositing an insulating material, an etch back process is performed on the insulating material. In this manner, the side wall insulating film 45 is formed in the periphery of the gate insulating film 41, the semiconductor film 42, the gate electrode film 43, and the insulating film 44. The side wall insulating film 45 overlaps the gate insulating film 41, the semiconductor film 42, the gate electrode film 43, and the insulating film 44 in a direction perpendicular to the Z-direction (X-direction, for example). The insulating film 31 is formed over the substrate 10, the device isolation films STI, the side wall insulating film 45, and the side wall insulating film 45.

An ion implantation process is performed on the substrate 10 with the insulating film 44 and the side wall insulating film 45 as a mask. In this manner, the first semiconductor region 11 and the second semiconductor region 12 are formed on the substrate 10. The insulating film 44, the gate electrode film 43, the semiconductor film 42, the gate insulating film 41, and the region between the first semiconductor region 11 and the second semiconductor region 12 overlap in the Z-direction.

As illustrated in FIG. 3, by depositing an insulating material containing a silicon oxide, for example, the insulating layer 30a (first insulating layer) is formed on the insulating film 31. Then, a planarization process is performed by chemical mechanical polishing (CMP) or the like. In this manner, a portion of the insulating layer 30a is removed over the insulating film 44.

A stopper film 13 is formed over the insulating layer 30a and the insulating film 44. The stopper film 13 is formed using an insulating material containing a silicon nitride, for example. Next, a resist film is formed on the stopper film 13. The resist film is processed into a prescribed pattern. In this manner, resist patterns 11a and 12a are formed. The resist pattern 11a and the resist pattern 12b are formed with a gap therebetween. The resist pattern 11a and the first semiconductor region 11 overlap in the Z-direction.

As illustrated in FIG. 4, anisotropic etching such as RIE is performed with the resist patterns 11a and 12a as masks. In this manner, portions of the stopper film 13 that are not covered by the resist patterns 11a and 12a are removed. Remaining portions of the stopper film 13 become the first stopper film 46 and the second stopper film 47. The first stopper film 46 and the first semiconductor region 11 overlap in the Z-direction. The second stopper film 47 and the second semiconductor region 12 overlap in the Z-direction.

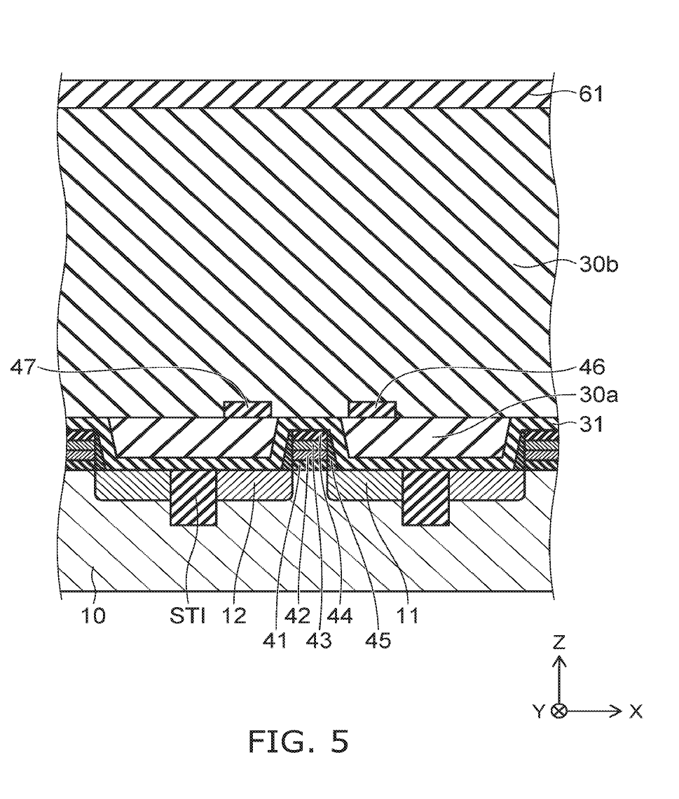

As illustrated in FIG. 5, the insulating layer 30b (second insulating layer) is formed on the insulating layer 30a, the insulating film 31, the first stopper film 46, and the second stopper film 47. The insulating film 61 is formed on the insulating layer 30b. The insulating layer 30b and the insulating film 61 are formed using an insulating material containing a silicon oxide, for example.

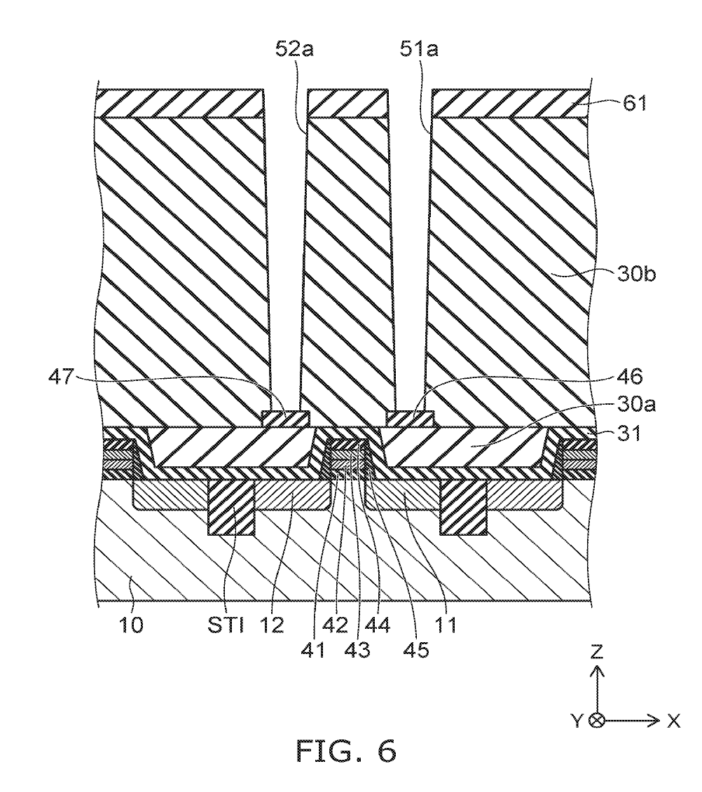

As illustrated in FIG. 6, anisotropic etching such as RIE is performed on the insulating film 61 and the insulating layer 30b. In this manner, a first contact hole 51a is formed on the first stopper film 46. A second contact hole 52a is formed on the second stopper film 47. At this time, etching is performed at a higher etching rate for the insulating film 61 and the insulating layer 30b than for the first stopper film 46 and the second stopper film 47. In other words, by performing anisotropic etching with the first stopper film 46 and the second stopper film 47 as etching stoppers, the first contact hole 51a and the second contact hole 52a are formed.

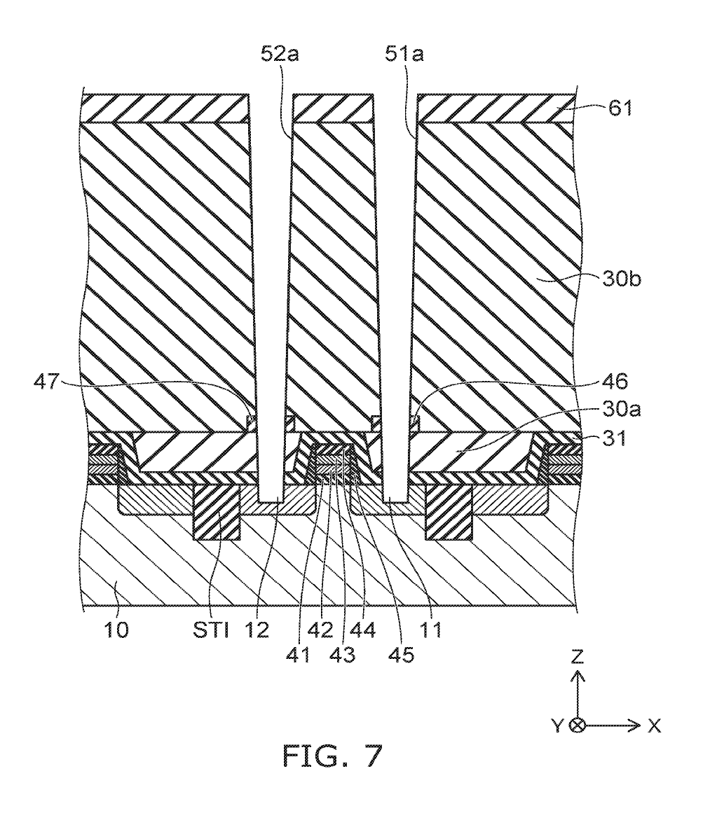

As illustrated in FIG. 7, etching is performed through the first contact hole 51a and the second contact hole 52a according to etching conditions that differ from when the insulating film 61 and the insulating layer 30b are etched. In this manner, the first contact hole 51a and the second contact hole 52a are extended in the Z-direction. Thus, the first contact hole 51a penetrates the first stopper film 46 and the insulating layer 30a and reaches the first semiconductor region 11. The second contact hole 52a penetrates the second stopper film 47 and the insulating layer 30a and reaches the second semiconductor region 12.

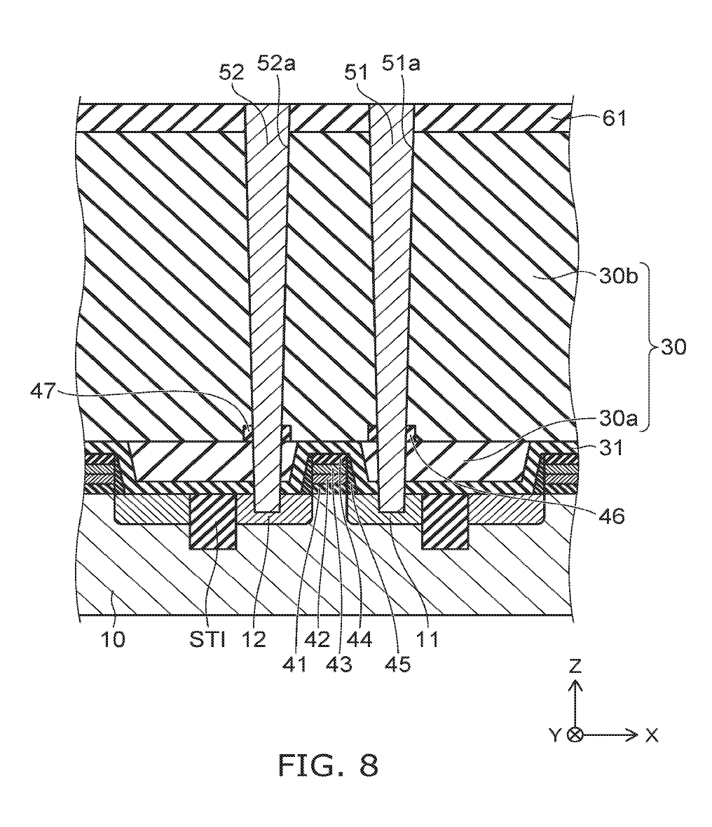

As illustrated in FIG. 8, the first contact hole 51a and the second contact hole 52a are filled with a conductive material such as tungsten. In this manner, the first contact plug 51 is formed in the first contact hole 51a. The second contact plug 52 is formed in the second contact hole 52a. The first contact plug 51 is electrically connected to the first semiconductor region 11. The second contact plug 52 is electrically connected to the second semiconductor region 12.

Then, the insulating film 62 is formed on the insulating film 61, the first contact plug 51, and the second contact plug 52. In the insulating film 62, the first plug 53 is formed on the first contact plug 51. In the insulating film 62, the second plug 54 is formed on the second contact plug 52. In the insulating film 62, the first interconnection 55 extending in the Y-direction, for example, is provided on the first plug 53. In the insulating film 62, the second interconnection 56 extending in the Y-direction, for example, is provided on the second plug 54. The insulating film 63 is formed on the insulating film 62, the first interconnection 55, and the second interconnection 56. The insulating film 64 is formed on the insulating film 63. Then, sintering is performed in a hydrogen atmosphere. As a result, as illustrated in FIG. 1, the peripheral circuit region 10b is formed.

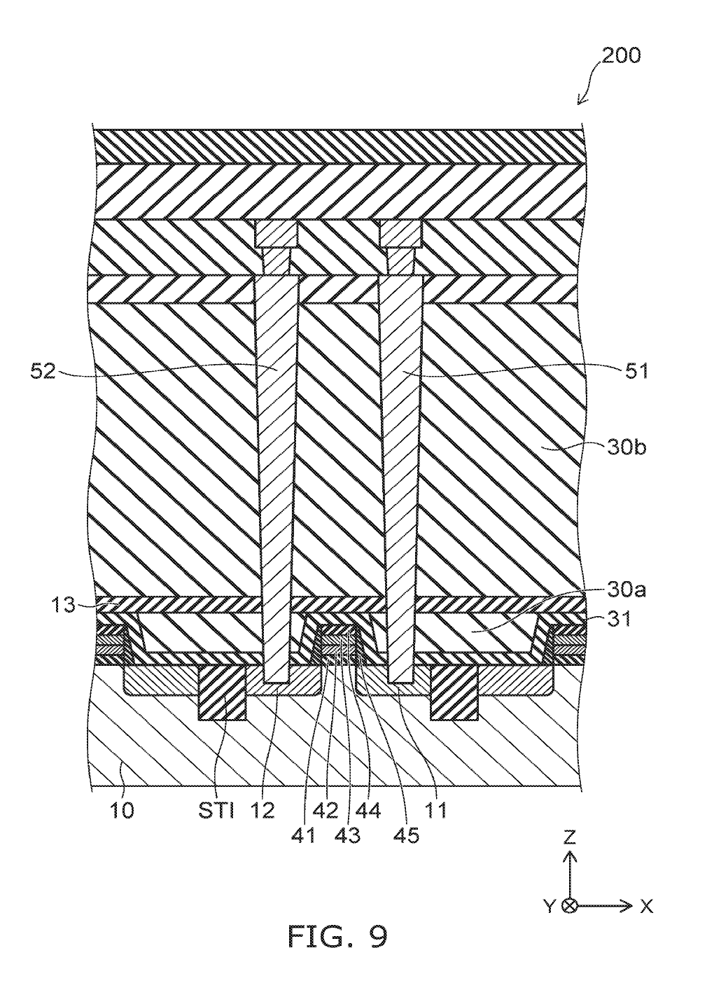

FIG. 9 is a cross-sectional view illustrating another example of a semiconductor memory device.

In the peripheral circuit region 10b, it is possible to conceive of using the stopper film 13 containing a silicon nitride as an etching stopper when forming the first contact hole 51a and the second contact hole 52a. In other words, it is possible to conceive of omitting the process of processing the first stopper film 46 and the second stopper film 47. In such a case, the stopper film 13 is provided over the entire surface of the substrate 10 in the peripheral circuit region 10b as in the semiconductor memory device 200 illustrated in FIG. 9. When performing the sintering process in a hydrogen atmosphere, the stopper film 13 containing the silicon nitride can prevent hydrogen molecules from reaching the device isolation films STI and the gate insulating film 41, which is a portion that operates as a transistor. Also, when performing the sintering process, hydrogen radicals are sometimes generated from the stopper film 13. When hydrogen radicals reach the device isolation films STI and/or the gate insulating film 41, these hydrogen radicals can cause defects in the device isolation films STI and/or the gate insulating film 41. That is, in the device isolation films STI and/or the gate insulating film 41, the hydrogen radicals cause hydrogen bonded with silicon atoms to separate therefrom, resulting in the silicon atoms having dangling bonds. Dangling bonds in the device isolation films STI and/or the gate insulating film 41 are electron trap sites.

In the embodiment, the stopper film 13 is processed into the first stopper film 46 and the second stopper film 47. In other words, portions of the stopper film 13 functioning as an etching stopper when forming the first contact hole 51a and the second contact hole 52a are left remaining, and other portions of the stopper film 13 are removed. In this manner, as illustrated in FIG. 1, the area where the stopper film containing a silicon nitride is provided on the substrate 10 in the peripheral circuit region 10b is reduced. In other words, when performing the sintering process under a hydrogen atmosphere, the hydrogen molecules more easily reach the device isolation films STI and/or the gate insulating film 41. This results in improved quality of the device isolation films STI and/or the gate insulating film 41. Additionally, fewer hydrogen radicals are generated, which suppresses deterioration in the film quality of the device isolation films STI and/or the gate insulating film 41.

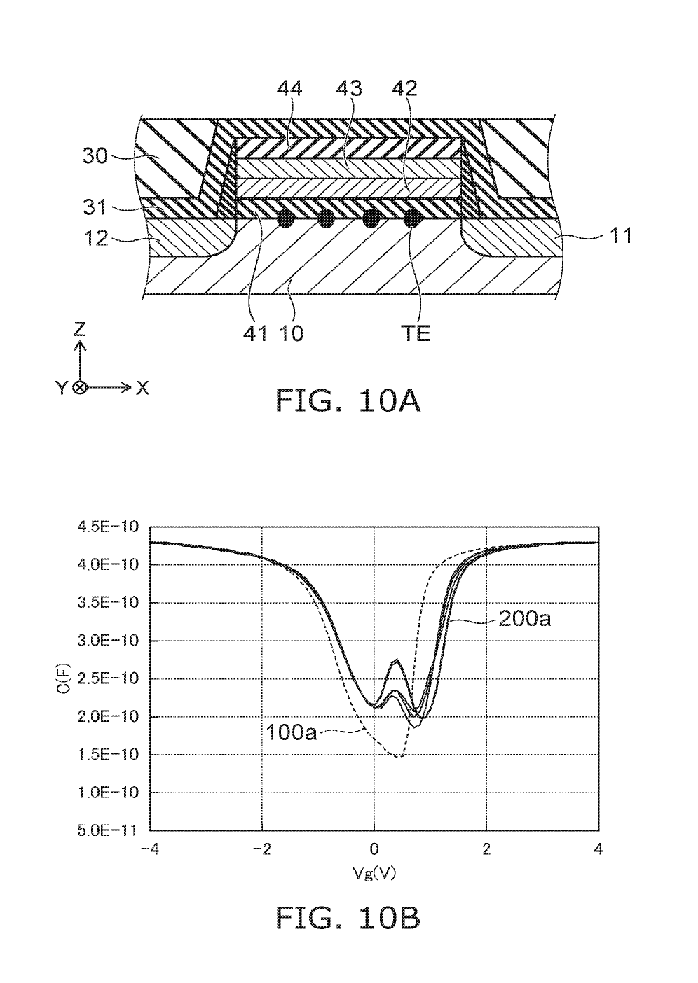

FIG. 10A is a cross-sectional view illustrating a region corresponding to the region R1 illustrated in FIG. 1, and FIG. 10B is a graph showing the relation between gate voltage and capacitance.

In FIG. 10B, the horizontal axis indicates the voltage applied to the gate electrode film 43, that is, the gate voltage Vg (V), and the vertical axis indicates the interface state between the substrate 10 and the gate insulating film 41 and the capacitance C (F) in the vicinity of the interface.

As illustrated in FIG. 10A, electrons are sometimes trapped in the interface state between the gate insulating film 41 and the substrate 10 or the vicinity of the interface. By performing the sintering process in a hydrogen atmosphere, the interface state density is reduced. The semiconductor memory device 100 and the semiconductor memory device 200 are sintered under the same conditions in a hydrogen atmosphere.

The data 100a indicated with the broken line in FIG. 10B is an example of data in the semiconductor memory device 100 provided with the first stopper film 46 and the second stopper film 47. The data 200a indicated with the solid line in FIG. 10B is an example of data in the semiconductor memory device 200 of another example illustrated in FIG. 9. In the peripheral circuit region 10b of the semiconductor memory device 200, the stopper film 13 containing a silicon nitride is provided above the substrate 10, the first semiconductor region 11, the second semiconductor region 12, the device isolation films STI, and the gate electrode film 43.

As illustrated in FIG. 10B, the data 100a forms a smooth curve having a bottom value around when the gate voltage Vg is close to 0 V. On the other hand, the data 200a includes a plurality of peak values (maximum values) when the gate voltage Vg is close to 0 V. The capacitance C for the data 200a when the gate voltage Vg is close to 0 V is greater than the capacitance C for the data 100a when the gate voltage Vg is close to 0 V. In other words, more electric charge is trapped in the interface state or the vicinity of the interface in the semiconductor memory device 200 than in the interface state or the vicinity of the interface in the semiconductor memory device 100. Thus, in the semiconductor memory device 200, the effect of the sintering process under a hydrogen atmosphere is stopped by the stopper film 13.

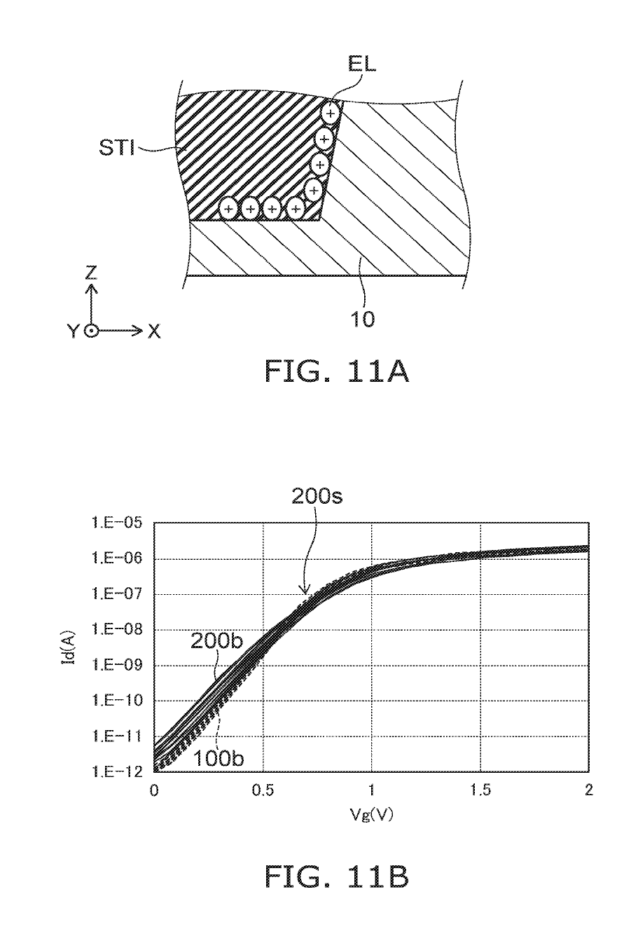

FIG. 11A is a cross-sectional view illustrating a region corresponding to the region R2 illustrated in FIG. 1, and FIG. 11B is a graph illustrating the relation between the drain current and the gate voltage.

FIG. 11B is a graph in which the horizontal axis is the gate voltage Vg (V) and the vertical axis is the drain current Id (A). The data 100b indicated with the broken line in FIG. 11B is an example of data in the semiconductor memory device 100, and the data 200b indicated with the solid line is an example of data in the semiconductor memory device 200.

As illustrated in FIG. 11A, in some cases, a fixed charge is generated in the vicinity of the interface between the device isolation films STI and the substrate 10. By performing the sintering process under a hydrogen atmosphere, the amount of fixed charge generated between the device isolation films STI and the substrate 10 is reduced.

As illustrated in FIG. 11B, in the data 100b, as the gate voltage Vg (V) rises, the drain current Id (A) also rises proportionally therewith. When the gate voltage Vg (V) is around 1 V, the drain current Id reaches a plateau. On the other hand, in the data 200b, the drain current Id (A) rises proportionally with the gate voltage Vg (V) until the gate voltage Vg (V) reaches around 0.6 V. However, a portion 200s is found around 0.7 V in which the rate at which the drain current Id (A) rises decreases. In the semiconductor memory device 200, the fixed charges EL generated in the vicinity of the interface between the device isolation films STI and the substrate 10 affect the drain current Id (A). In other words, in the semiconductor memory device 200, the effect of the sintering process under a hydrogen atmosphere is stopped by the stopper film 13.

According to the embodiments described above, it is possible to realize a semiconductor device with improved transistor characteristics and a manufacturing method for the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a substrate including a first substrate region, a second substrate region arranged with the first substrate region in a first direction, and an intermediate region disposed between first substrate region and second substrate region;
a first semiconductor region provided in the first substrate region, and a second semiconductor region provided in the second substrate region;
an insulating layer provided on the intermediate region, on the first semiconductor region, and on the second semiconductor region;
a gate electrode film provided between the intermediate region and the insulating layer;
a gate insulating film provided between the intermediate region and the gate electrode film;
a first film provided in the insulating layer;
a second film provided in the insulating layer, at least a portion of the second film overlapping at least a portion of the first film in the first direction;
a first contact plug extending in the insulating layer and the first film along a second direction crossing the first direction, the first contact plug being electrically connected to the first semiconductor region; and
a second contact plug extending in the insulating layer and the second film along the second direction, the second contact plug being electrically connected to the second semiconductor region,
at least a part of the gate electrode film not overlapping the first film in the second direction and not overlapping the second film in the second direction.

2. The device according to claim 1, wherein
at least a part of the first film overlaps the first semiconductor region in the second direction, and
at least a part of the second film overlaps at least a apart of the second semiconductor region in the second direction.

3. The device according to claim 1, wherein
the first film and the second film contain a silicon nitride.

4. The device according to claim 1, wherein
an etching rate of the first film under a first processing condition is lower than an etching rate of the insulating layer under the first processing condition.

5. The device according to claim 1, wherein
an etching rate of the second film under a first processing condition is lower than an etching rate of the insulating layer under the first processing condition.

6. The device according to claim 1, further comprising:
a structure provided on the substrate and in a periphery of the insulating layer, the structure including a plurality of electrode films arranged in the second direction;
a column extending along the first direction in the structure; and
a memory film provided between the column and the structure.

7. The device according to claim 1, further comprising:
a device isolation film provided between the insulating layer and a part of the substrate,
the first semiconductor region being disposed between the device isolation film and the intermediate region, and
at least a part of the device isolation film not overlapping the first film in the second direction and not overlapping the second film in the second direction.

8. A semiconductor memory device comprising:
a first insulating layer;
a second insulating layer provided on the first insulating layer;
a first film and a second film being provided between the first insulating layer and the second insulating layer, the second film being separated from the first film;
a first contact plug having a first side surface, the first side surface being in contact with the first insulating layer, the second insulating layer, and the first film;
a second contact plug having a second side surface, the second side surface being in contact with the insulating film, the insulating layer, and the second film; and
a transistor including a source and a drain, the first contact plug being electrically connected to one of the source and the drain, the second contact plug being connected to other one of the drain and the source.

9. The device according to claim 8, wherein
the first film and the second film contain a silicon nitride and the first insulating layer and the second insulating layer contain a silicon oxide.

10. The device according to claim 8, wherein
an etching rate of the first film under a first processing condition is lower than an etching rate of the second insulating layer under the first processing condition.

11. The device according to claim 8, wherein
an etching rate of the second film under a first processing condition is lower than an etching rate of the second insulating layer under the first processing condition.

12. The device according to claim 8, wherein
a part of the second insulating layer is disposed between the first film and the second film.

13. The device according to claim 12, wherein
an top surface of the first film, a side surface of the first film, an top surface of the second film, and a side surface of the second film are seamless with the second insulating layer.

14. The device according to claim 12, wherein the second film is discontinuous with the first film.

15. A method for manufacturing a semiconductor memory device comprising:
forming a gate insulating film on a third region of a substrate, the third region being provided between a first region of the substrate and a second region of the substrate;
forming a gate electrode film on the gate insulating film;
forming an insulating film on the gate electrode film;
forming a first semiconductor region in the first region and a second semiconductor region in the second region by performing an ion implantation process, the second semiconductor region being separated from the first semiconductor region in a first direction;
forming a first insulating layer on the third region, on the first semiconductor region, and on the second semiconductor region;
forming a first film and a second film on the first insulating layer, at least a part of the first film overlapping at least a part of the first semiconductor region in a second direction crossing the first direction, and at least a part of a second film overlapping at least a part of the second semiconductor region in the second direction;
forming a second insulating layer on the first insulating layer, the first film, and the second film;
forming a first contact hole and a second contact hole, the first contact hole penetrating the second insulating layer, the first film, and the first insulating layer, the second contact hole penetrating the second insulating layer, the second film, and the first insulating layer; and
forming a first contact plug in the first contact hole and a second contact plug in the second contact hole.

16. The method according to claim 15, wherein
the forming the first film and the second film includes
forming a third film on the first insulating layer;
forming a first resist pattern and a second resist pattern on the third film, at least a part of the first resist pattern overlapping at least a part of the first semiconductor region in the second direction, and at least a part of the second resist pattern overlapping at least a part of the second semiconductor region in the second direction; and
etching the third film using the first resist pattern and the second resist pattern as a mask to form the first film and the second film.

17. The method according to claim 15, wherein
the forming the first contact hole and the second contact hole includes
a first etching the second insulating layer under a first condition by using the first film and the second film as an etching stopper; and
a second etching the first film, the second film, and the first insulating layer under a second condition different from the first condition.

18. The method according to claim 15, wherein
the first insulating layer and the second insulating layer are formed from a material containing a silicon oxide, and
the first film and the second film are formed from a material containing a silicon nitride.
